(19) United States
(12) Patent Application Publication
(10) Pub. No.: US 2018/0198087 A1
(43) Pub. Date: Jul. 12, 2018

(54) Organic light-emitting component and method for producing an organic light-emitting component

(71) Applicant: OSRAM OLED GmbH, Regensburg (DE)

(72) Inventors: Johannes Rosenberger, Regensburg (DE); Daniel Riedel, Regensburg (DE); Thomas Wehlus, Lappersdorf (DE)

(21) Appl. No.: 15/741,515

(22) PCT Filed: Jun. 22, 2016
(86) PCT No.: PCT/EP2016/064371

§ 371 Date: Jan. 3, 2018

(30) Foreign Application Priority Data
Jul. 3, 2015 (DE) 10 2015 212 477.0

(51) Int. Cl. H01L 51/52; H01L 51/56

(52) U.S. Cl. CPC H01L 51/5237; H01L 2251/301; H01L 51/56

(57) ABSTRACT

An organic light-emitting component may include: a substrate, a first electrode arranged over the substrate, at least one organic functional layer stack configured to emit radiation and arranged over the first electrode, at least one conductive current spreading structure which is arranged on the first electrode and faces the at least one organic functional layer stack, and a second electrode arranged over the at least one organic functional layer stack. The at least one conductive current spreading structure may comprise at least one metal, and may be covered with an inorganic passivation layer. The inorganic passivation layer may comprise a sulfide, a selenide and/or a telluride of the at least one metal. The inorganic passivation layer may be an n-type or p-type semiconductor, such that no current flows between the least one conductive current spreading structure and the at least one organic functional layer stack via the inorganic passivation layer.

### CROSS-REFERENCE TO RELATED APPLICATIONS

This application is a national stage entry of International Application No. PCT/EP2016/064371 under 35 U.S.C. §§ 365 and 371, filed on Jun. 22, 2016, which claims priority to German Patent Application No. 10 2015 212 477.0, which was filed on Jul. 3, 2015. The disclosures of each of the foregoing documents are incorporated herein by reference in their entirety and for all purposes.

### FIELD

The disclosure relates to an organic light-emitting component. Furthermore, the disclosure relates to a method for producing an organic light-emitting component.

### BACKGROUND

Conductive current spreading structures can be applied for example on a first electrode of an organic light-emitting component, for example of an organic light-emitting diode (OLED), in order to achieve a uniform emission of the light or a desired emission of the light via the luminous area. The conductive current spreading structures generally have to be covered with an insulation layer, for example composed of an organic non-conductive resist material or a non-conductive oxide or nitride, in order that charge carriers are injected into the organic layer stack only via the first electrode and not via the conductive current spreading structures. This has the disadvantage, however, that an additional process step has to be carried out in order to apply the insulation layer separately. Furthermore, in the case of organic insulation layers, in particular, in a manner governed by the fabrication process, decomposition products can penetrate into the regions that are important for the emission properties, for example regions of the organic functional layer stack, and can thus reduce the lifetime of the OLED. Furthermore, this can result in a constriction of the luminous area. Furthermore, the height as viewed in cross section for the encapsulation can be unfavorable with the use of an insulation layer composed of a non-conductive resist material, for example.

### SUMMARY

One aspect to be achieved consists in overcoming the disadvantages mentioned above. A further aspect to be achieved consists in providing an organic light-emitting component which is producible more rapidly, more simply and/or more cost-effectively.

Said aspect or said aspects may be achieved by means of an organic light-emitting component as disclosed herein. Furthermore, said aspect or said aspects may be achieved by means of a method for producing an organic light-emitting component as disclosed herein. Advantageous configurations and developments are the subject matter of the present disclosure.

In at least one embodiment, the organic light-emitting component includes a substrate. A first electrode is arranged over the substrate. At least one organic functional layer stack which is configured for emitting radiation is arranged over the first electrode. At least one conductive current spreading structure is arranged on the first electrode. In particular, the conductive current spreading structure faces the organic functional layer stack. The conductive current spreading structure includes at least one metal. The conductive current spreading structure is covered with an inorganic passivation layer. The inorganic passivation layer includes or consists of a sulfide, selenide and/or telluride of the at least one metal of the conductive current spreading structure. In particular, the conductive current spreading structure includes at least one metal or an alloy composed of at least two metals. In particular, the inorganic passivation layer then consists of a sulfide, selenide and/or telluride of the alloy of the conductive current spreading structure. The inorganic passivation layer is either an n-type semiconductor or a p-type semiconductor, such that no current flows, in particular no current flows vertically, between the conductive current spreading structure and the organic functional layer stack via the inorganic passivation layer. The organic light-emitting component includes a second electrode arranged over the organic functional layer stack.

In accordance with at least one embodiment, the conductive current spreading structure is electrically conductive. Preferably, the conductive current spreading structure is metallic.

Alternatively or additionally, at least one conductive current spreading structure can be arranged between the substrate and the first electrode, that is below the first electrode.

Alternatively or additionally, the organic light-emitting component may include at least one conductive current spreading structure which is arranged at least between the one organic functional layer stack and the second electrode. In particular, the conductive current spreading structure faces the organic functional layer stack.

In accordance with at least one embodiment, the organic light-emitting component is shaped as an organic light-emitting diode (OLED).

In accordance with at least one embodiment, the organic light-emitting component includes a substrate. The substrate may include for example one or a plurality of materials in the form of a layer, a plate, a film or a laminate, which are selected from glass, quartz, plastic, metal, silicon wafer, ceramic, coated paper. Particularly preferably, the substrate includes glass, for example in the form of a glass layer, glass film or glass plate, or is composed thereof.

In accordance with at least one embodiment, the organic light-emitting component includes a first and second electrode. In particular, at least one electrode can be formed as transparent. Here and hereinafter, transparent denotes a layer which is transmissive to visible light. In this case, the transparent layer can be clearly translucent or at least partly light-scattering and/or partly light-absorbing, such that the transparent layer can also be diffusively or milkily translucent, for example. Particularly preferably, a layer designated here as transparent is as light-transmissive as possible, such that in particular the absorption of light generated in the organic functional layer stack during the operation of the organic light-emitting component is as low as possible.

Alternatively, both electrodes can also be shaped as transparent. The radiation generated in the at least one organic functional layer stack can thus be emitted in both directions, that is to say through both electrodes. For the case where the organic light-emitting component includes a substrate, that means that the radiation can be emitted both through the substrate, which is then likewise formed as transparent, and in the direction facing away from the substrate. Furthermore, in this case, all layers of the organic light-emitting component can be formed as transparent, such that the organic light-emitting component forms a transparent OLED. Furthermore, it can also be possible for one of the two electrodes between which the organic functional layer stack is arranged to be formed as non-transparent and preferably reflective, such that the radiation generated in the organic functional layer stack can be emitted only in one direction through the transparent electrode. If the electrode arranged on the substrate is transparent, and the substrate is also formed as transparent, then this is also referred to as a so-called bottom emitter, while in the case where the electrode arranged in a manner facing away from the substrate is formed as transparent, this is referred to as a so-called top emitter.

By way of example, a transparent conductive oxide (TCO), such as ITO, for example, can be used as material for a transparent electrode.

Transparent electrically conductive oxides (TCO) are transparent electrically conductive materials, generally metal oxides, such as, for example, zinc oxide, tin oxide, cadmium oxide, titanium oxide, indium oxide, indium tin oxide (ITO) or aluminum zinc oxide (AZO). Alongside binary metal-oxygen compounds such as, for example, ZnO, SnO₂ or In₂O₃, ternary metal-oxygen compounds such as, for example, Zn₂SnO₄, CdSnO₃, ZnSnO₃, MgIn₂O₄, GaInO₃, Zn₂In₂O₅ or In₄Sn₃O₁₂ or mixtures of different transparent conductive oxides also belong to the group of TCOs. Furthermore, the TCOs do not necessarily correspond to a stoichiometric composition and can also be p- or n-doped.

Furthermore, a transparent electrode may also include a metal layer including a metal or an alloy, for example including one or a plurality of the following materials: silver, platinum, gold, magnesium or an alloy composed of silver and magnesium. Furthermore, other metals are also possible. In this case, the metal layer has such a small thickness that it is at least partly transmissive to the light generated by the organic functional layer stack, for example a thickness of less than or equal to 50 nm.

As material for a reflective electrode it is possible to use a metal, for example, which can be selected from aluminum, barium, indium, silver, gold, magnesium, calcium and lithium and compounds, combinations and alloys thereof. In particular, a reflective electrode may include silver, aluminum or alloys including these, for example Ag:Mg, Ag:Ca, Mg:Al.

In particular, the electrodes can be nanostructured electrodes, for example silver nanowires, or be composed of graphene.

In accordance with at least one embodiment, the first electrode is formed as an anode, and then the second electrode is formed as a cathode. Alternatively, the first electrode can be formed as a cathode, and then the second electrode is formed as an anode.

The electrodes may also include a combination of at least one or a plurality of TCO layers and at least one or a plurality of metal layers.

In accordance with at least one embodiment, at least one organic functional layer stack is arranged over the first electrode and/or the substrate. The fact that one layer or one stack is arranged or applied “on” or “over” another layer or stack can in this case mean here and hereinafter that said one layer or one stack is arranged directly in direct mechanical and/or electrical contact on the other layer or the other stack. Furthermore, it can also mean that said one layer is arranged indirectly on or above or over the other layer or the other stack. In this case, further layers or stacks can then be arranged between said one layer or stack and the other layer or stack.

In accordance with at least one embodiment, the organic light-emitting component includes at least one organic functional layer stack. In particular, the organic light-emitting component includes exactly one organic functional layer stack. During the operation of the organic light-emitting component, radiation is generated in the organic functional layer stack. A wavelength of the radiation or the wavelength maximum is preferably in the infrared and/or ultraviolet and/or visible spectral range, in particular at wavelengths of between 420 nm and 680 nm inclusive.

The organic functional layer stack may include layers including organic polymers, organic oligomers, organic monomers, organic small non-polymeric molecules (“small molecules”) or combinations thereof. The organic functional layer stack may additionally include further functional layers embodied as a hole transport layer in order to enable an effective injection of holes into the at least one organic functional layer stack. By way of example, tertiary amines, carbazole derivatives, polyaniline doped with camphorsulfonic acid or polyethylene dioxythiophene doped with polystyrenesulfonic acid can prove to be advantageous as materials for a hole transport layer. The organic functional layer stack may furthermore include at least one functional layer formed as an electron transport layer. Generally, the organic functional layer stack may include additional layers selected from hole injection layers, hole transport layers, electron injection layers, electron transport layers, hole blocking layers and electron blocking layers. In particular, the layers of the organic functional layer stack can be completely or at least predominantly organic functional layers. Furthermore, it can also be possible for individual layers of the organic functional layer stack also to include or to be formed from inorganic materials.

In accordance with at least one embodiment, the organic light-emitting component includes at least one conductive current spreading structure. The conductive current spreading structure is arranged on the first electrode. In particular, the conductive current spreading structure is arranged in direct electrical and/or mechanical contact on the first electrode. The conductive current spreading structure faces the organic functional layer stack, in particular. In other words, the conductive current spreading structure projects at least partly or completely into the organic functional layer stack. The conductive current spreading structures projecting only at least partly into the organic functional layer stack, also called outer conductive current spreading structures, can serve for direct contacting with the second electrode.

In particular, a plurality of conductive current spreading structures, for example eight to 50, can be present in an organic light-emitting component.

In accordance with at least one embodiment, the conductive current spreading structure includes at least one metal. In particular, the metal together with at least one further metal can form an alloy. Alloy can also mean that the at least one metal together with further metals forms a solid solution, for example CuInS₂. In particular, any metals can be used for the conductive current spreading structure. The resultant inorganic passivation layers, for example the sulfides, selenides and/or tellurides, should in this case have the property that they can be used as n-type semiconductors or p-type semiconductors. This can for example also be produced by doping during production. In particular, the metal or the alloy of the conductive current spreading structure is selected from a group including silver, aluminum, molybdenum, chromium, copper, magnesium or an alloy composed of molybdenum-aluminum (Mo:Al), chromium-aluminum (Cr:Al), silver-magnesium (Ag:Mg), and combinations thereof. Particularly preferably, the conductive current spreading structure is shaped from silver.

The conductive current spreading structure can also be a conductive glass, a conductive ceramic or a highly doped semiconductor. In particular, that is the case if the conductive current spreading structure is covered with a metal layer, preferably with silver.

In accordance with at least one embodiment, the conductive current spreading structure consists of a metal, in particular of silver. Alternatively, the conductive current spreading structure can have a layer construction. By way of example, the current spreading structure may include three layers composed of two or three different metals. In particular, the conductive current spreading structure has a layer structure including at least two silver layers, wherein the two silver layers are separated from one another by a further metal layer. In particular, the further metal layer is shaped from a metal.

The conductive current spreading structures can have any arbitrary shape. In particular, the conductive current spreading structures can be lead structures running parallel to one another in a plan view of the organic light-emitting component. The lead structures running parallel can be at an identical distance or a different distance from one another. In the case where the lead structures are at an identical distance from one another, a uniform emission of the radiation or a desired emission of the radiation via the luminous area can be generated.

Alternatively or additionally, the conductive current spreading structure can be configured in the shape of a rectangle or in a honeycomb shape.

In accordance with at least one embodiment, the conductive current spreading structure is applied directly on the first electrode, which is shaped in particular as transparent. The application can be carried out for example by means of sputtering or physical vapor deposition (PVD for short).

In accordance with at least one embodiment, the conductive current spreading structure is covered with an inorganic passivation layer. The conductive current spreading structure has a surface facing away from the substrate, and side faces. In particular, both the surface and the side faces are covered with the inorganic passivation layer. Here and hereinafter, “covered” means that the inorganic passivation layer envelops or covers the side faces and the surface of the conductive current spreading structure over the whole area. In particular, the inorganic passivation layer envelops the surface and side face of the conductive current spreading structure in a positively locking manner.

In accordance with at least one embodiment, the inorganic passivation layer directly covers the surface facing away from the substrate and the side faces of the conductive current spreading structure. Here and hereinafter, “directly” means that the inorganic passivation layer is arranged in direct mechanical contact on the surface and also on the side faces of the conductive current spreading structure. In other words, no further layers or elements are arranged between the surface and/or side faces of the conductive current spreading structure and the inorganic passivation layer.

In accordance with at least one embodiment, the inorganic passivation layer includes or consists of a sulfide and/or selenide and/or telluride of the at least one metal or of the alloy of the conductive current spreading structure. In particular, the inorganic passivation layer is free of organic resist materials, metal oxides, nitrides and/or silicon oxide.

In accordance with at least one embodiment, the inorganic passivation layer is an n-type semiconductor. Alternatively, the inorganic passivation layer is a p-type semiconductor.

Here and hereinafter, n-type semiconductor denotes the fact that the inorganic passivation layer is capable of conducting electrons and prevents the conduction of holes. In other words, the inorganic passivation layer shaped as an n-type semiconductor acts as a hole insulating area. The injection of holes from the conductive current spreading structure into the adjoining hole transport layers and/or hole injection layers and/or the organic functional layer stack is thus prevented.

Here and hereinafter, p-type semiconductor denotes the fact that the inorganic passivation layer conducts the holes and prevents the conduction of electrons. The inorganic passivation layer shaped as an n-type or p-type semiconductor makes it possible for no current to flow, in particular no current to flow directly and/or vertically, between the conductive current spreading structure and the organic functional layer stack via the inorganic passivation layer.

In the case where the inorganic passivation layer is shaped as an n-type semiconductor, that means that transport of holes from the first electrode, shaped as an anode, via the inorganic passivation layer in the direction of the organic functional layer stack is prevented. In the case of an inorganic passivation layer shaped as a p-type semiconductor, that means that transport of electrons from the first electrode, shaped as a cathode, via the inorganic passivation layer in the direction of the organic functional layer stack is prevented.

In accordance with at least one embodiment, the inorganic passivation layer is produced by sulfidizing the at least one metal of the conductive current spreading structure. In other words, the metal or the alloy of the conductive current spreading structure is treated here with an atmosphere containing sulfur ions, a solution containing sulfur ions and/or a plasma containing sulfur ions, such that an inorganic passivation layer which includes or consists of a sulfide is produced from the metal of the conductive current spreading structure.

In accordance with at least one embodiment, the first electrode is shaped as an anode. In particular, the anode is transparent. The inorganic passivation layer is an n-type semiconductor, such that transport of holes from the first electrode via the inorganic passivation layer in the direction of the organic functional layer stack is prevented. In other words, the inorganic passivation layer has an insulating effect for the holes emitted by the anode. The inorganic passivation layer is transmissive to electrons.

In accordance with at least one embodiment, the conductive current spreading structure includes a metal, preferably silver. The inorganic passivation layer includes or consists of a metal sulfide, preferably silver sulfide. In particular, the inorganic passivation layer is produced by sulfidizing the metal, preferably silver, of the conductive current spreading structure. Production can be carried out for example by means of a hydrogen sulfide atmosphere. In particular, the metal, preferably silver, of the conductive current spreading structure is sulfidized only superficially. An n-type semiconductor, preferably silver sulfide (Ag₂S), having non-hole-conducting properties is produced as a result. Silver sulfide is a chemical compound from the group of sulfides which arises from a chemical reaction of sulfur and silver.

In accordance with at least one embodiment, the organic light-emitting component is configured to emit the radiation generated by the organic functional layer stack via the first electrode and the substrate. In other words, the organic light-emitting component is shaped as a bottom emitter.

In accordance with at least one embodiment, the conductive current spreading structure includes or consists of a metal, preferably silver. The inorganic passivation layer is produced by telluridizing at least the metal, preferably silver, of the conductive current spreading structure. In other words, an inorganic passivation layer which includes or consists of a metal telluride, preferably silver telluride (Ag₂Tr), is produced from the metal, preferably silver, of the conductive current spreading structure. Silver telluride is a monoclinic crystal compound from the group of tellurides which is formed from silver and tellurium in a high-temperature process. Silver telluride is an n-type semiconductor, in particular. Preferably, the first electrode is then shaped as an anode in that case.

In accordance with at least one embodiment, the inorganic passivation layer is produced by selenidizing at least the metal of the conductive current spreading structure. The inorganic passivation layer then includes or consists of at least one selenide.

The inventors have recognized that as a result of the use of an inorganic passivation layer which is either an n-type semiconductor or a p-type semiconductor and includes a sulfide, selenide and/or telluride of the at least one metal of the conductive current spreading structure, no restructuring has to be carried out. Furthermore, it is possible to apply the inorganic passivation layer in a simple reactive process step. In particular, the inorganic passivation layer is formed from a silver sulfide, silver selenide and/or silver telluride, preferably a silver sulfide. Alternatively, silver sulfide, silver selenide and/or silver telluride can additionally be n-doped. Silver is the material having the highest known electrical conductivity. As a result, given the same layer thickness as in the hitherto customary conductive current spreading structures having for example a layer construction composed of chromium, aluminum and chromium, a higher conductivity can be achieved, or the layer thickness can be reduced to achieve the same conductivity of the previous layer stack.

In accordance with at least one embodiment, the first or the second electrode is shaped as a cathode. The inorganic passivation layer is a p-type semiconductor, such that transport of electrons from the first electrode or the second electrode via the inorganic passivation layer in the direction of the organic functional layer stack is prevented. In other words, the first or second electrode is shaped as a cathode and configured to emit electrons in the direction of the organic functional layer stack. Since the inorganic passivation layer is formed as a p-type semiconductor and is therefore only transmissive to holes, the inorganic passivation layer acts as an electron insulating layer in that case. Therefore, no electrons are transported into the organic functional layer stack via the inorganic passivation layer.

In accordance with at least one embodiment, the second electrode is shaped as a cathode. In particular, the organic light-emitting component is shaped as a transparent OLED. This means that the radiation generated by the organic functional layer stack is emitted both via the first electrode and via the second electrode. The second electrode in particular then includes an inorganic passivation layer which is a p-type semiconductor. In addition, in particular the first electrode includes an inorganic passivation layer which is formed as an n-type semiconductor. The respective passivation layers thus act as a hole or electron insulator. A direct current flow through the respective passivation layers is thus prevented.

In accordance with at least one embodiment, the inorganic passivation layer is a mixture of at least two different metal sulfides. In particular, each metal sulfide of the mixture is an n-type or p-type semiconductor.

In accordance with at least one embodiment, the inorganic passivation layer has a layer thickness of between 10 nm and 100 nm inclusive, in particular of 5 nm to 50 nm. In particular, the inorganic passivation layer has a layer thickness of less than or equal to 10 nm. In particular, the layer thickness is thick enough to avoid the tunneling current. As a result, the tunneling current can be prevented and at the same time the conductive current spreading structures are virtually invisible since the inorganic passivation layer is shaped in a very thin fashion.

In accordance with at least one embodiment, the inorganic passivation layer is additionally or alternatively applied on the first electrode and/or the conductive current spreading structure, which is arranged at least outside the organic functional layer stack.

As a result of the use of an inorganic passivation layer on conductive current spreading structures, the latter are virtually invisible, compared with polyimide-coated conductive current spreading structures, since the inorganic passivation layer is shaped in a very thin fashion. Furthermore, the latter have a reliable insulation vis-à-vis holes or electrons. Moreover, the inorganic passivation layer is producible simply and inexpensively and is controllable very well in terms of its properties. The production of an inorganic passivation layer is easily integratable into existing processes, for example even if it is necessary to bake the substrates after cleaning. At the same time, the property of the first electrode, in particular composed of TCO, is also influenced since a lower voltage is necessary in the organic light-emitting component, which leads to a higher lifetime.

Since the conductive current spreading structures covered with an inorganic passivation layer are virtually invisible, these can be arranged arbitrarily to produce an intentional inhomogeneity, for example. The conductive current spreading structures have in particular a width of 50 μm. A wider resist is not necessary.

On account of their small size, the conductive current spreading structures covered with an inorganic passivation layer can be arranged very close together. This contributes to the fact that, starting from a certain distance, the conductive current spreading structures are no longer perceptible, that is to say that a blurring between a luminous area and a non-luminous conductive current spreading structure is produced. In particular, conductive current spreading structures can assume a width of 1 μm, in particular down to a minimum or up to a maximum of 1 μm.

Moreover, conductive current spreading structures covered with an inorganic passivation layer constitute a reliable insulation compared with current spreading structures coated by screen printing.

In accordance with at least one embodiment, the conductive current spreading structure has a surface facing away from the substrate, and side faces, wherein the inorganic passivation layer directly covers both the surface and the side faces.

In accordance with at least one embodiment, the conductive current spreading structure has or includes a metal layer. The conductive current spreading structure has a surface facing away from the substrate, and side faces. The metal layer covers, in particular directly, the surface facing away from the substrate and side faces of the conductive current spreading structure. “Directly” here means in direct mechanical contact. The inorganic passivation layer can be produced from the metal layer. In particular, the inorganic passivation layer is produced by sulfidizing, telluridizing and/or selenidizing the metal layer and is arranged at or covers at least the surface and the side faces of the conductive current spreading structure.

In other words, here a metal layer is applied on the conductive current spreading structure, wherein the thickness of the metal layer is arbitrarily adjustable. In this case, the metal layer molds around both the side faces and the surface of the conductive current spreading structure. Afterward, the metal layer can then be at least partly sulfidized, telluridized and/or selenidized, wherein the metal layer is at least partly converted into an inorganic passivation layer. It is thus possible to produce a uniform inorganic passivation layer made from a uniform material.

In accordance with at least one embodiment, the inorganic passivation layer has a thickness of less than or equal to 10 nm. In comparison with the conventional insulation layer, the inorganic passivation layer is impermeable with such a thickness.

In accordance with at least one embodiment, the metal layer includes or consists of silver. The inorganic passivation layer then includes or consists of silver sulfide.

In accordance with at least one embodiment, the organic light-emitting component includes an encapsulation. The encapsulation is preferably applied in the form of a thin film encapsulation on the organic light-emitting component. In particular, the encapsulation protects the at least one organic functional layer stack and the electrodes against the surroundings such as, for example, against moisture and/or oxygen and/or other corrosive substances. The encapsulation may include one or a plurality of thin layers which are applied for example by means of an atomic layer deposition method and which include for example one or more of the materials aluminum oxide, zinc oxide, zirconium oxide, titanium oxide, hafnium oxide, lanthanum oxide and tantalum oxide. The encapsulation may furthermore include on a thin film encapsulation, for example, a mechanical protection in the form of a plastics layer and/or a laminated glass layer, as a result of which anti-scratch protection, for example, can be achieved.

Alternatively, some other encapsulation can also be possible, for example in the form of an adhesively bonded glass cover. In particular, the glass cover or the glass is arranged on the thin film encapsulation by means of an adhesive or an adhesive layer. Alternatively, a cavity encapsulation including getter material can be used instead of a thin film coating (TFE).

The thin film encapsulation can be constructed e.g. as follows: a mixture of silicon nitride, of silicon oxide having an arbitrary oxidation number and silicon carbide in an arbitrary composition and order. Alternatively or additionally, it is possible to use an encapsulation composed of an aluminum oxide having an arbitrary oxidation number and a titanium oxide having an arbitrary oxidation number in an arbitrary thickness and order.

In accordance with at least one embodiment, the encapsulation has a layer thickness of 20 to 5000 nm. Especially for an encapsulation composed of silicon nitride, silicon oxide and silicon carbide, in particular the encapsulation has a layer thickness of 0.5 to 5 μm, for example 1 nm to 3 μm. For an encapsulation composed of aluminum oxide and titanium oxide, it is possible to use a layer thickness of 40 to 60 nm, for example 50 nm.

The disclosure furthermore relates to a method for producing an organic light-emitting component. An organic light-emitting component is preferably produced by the method. In this case, the same definitions and explanations as above for the organic light-emitting component also apply to the method, and vice versa.

In accordance with at least one embodiment, the method for producing an organic light-emitting component includes the following method steps:

A) providing a substrate,

B) applying a first electrode on the substrate,

C) applying at least one conductive current spreading structure on the first electrode. The conductive current spreading structure includes at least one metal and has a surface facing away from the substrate, and side faces.

D) selectively forming an inorganic passivation layer at least on the surface and the side faces of the conductive current spreading structure, wherein the inorganic passivation layer includes or consists of a sulfide, selenide and/or telluride of the at least one metal of the conductive current spreading structure.

The inorganic passivation layer is either an n-type or a p-type semiconductor, such that no current flows between the conductive current spreading structure and the organic functional layer stack via the inorganic passivation layer.

E) applying an organic functional layer stack at least on the inorganic passivation layer and at least partly on the first electrode,

F) applying a second electrode.

In accordance with at least one embodiment, before step D) an additional step C1) is carried out:

C1) selectively applying a protective layer on regions of the first electrode which are free of the conductive current spreading structure, and wherein after step D) an additional step D1) is carried out:

D1) removing the protective layer.

The protective layer has the effect that the first electrode is protected by step D), that is to say in particular is not sulfidized, telluridized or selenidized. The protective layer can be removed again by selective etching, ablation and/or lift-off methods.

In accordance with at least one embodiment, the sulfidizing in step D) is carried out by means of an atmosphere including hydrogen sulfide. The atmosphere including hydrogen sulfide can be produced for example by a hydrogen sulfide solution. In particular, the hydrogen sulfide solution includes at least 99% hydrogen sulfide. The atmosphere including hydrogen sulfide can be produced for example in a desiccator bell. Alternatively, the atmosphere including hydrogen sulfide can also be produced in a process chamber. In particular, the process chamber should be sealed from the environment in order to avoid damage to health resulting from hydrogen sulfide.

Alternatively, the sulfidizing in step D) can be carried out by means of a sulfur-containing solution, in particular a solution containing sulfur ions. In particular, step D) is then carried out by dipping. Any solution containing sulfur ions, such as ammonium sulfide ((NH₄)₂S), for example, can be used in this case.

Alternatively or additionally, the conductive current spreading structure, which consists of silver, in particular, can be treated by means of a sulfur-containing plasma, in particular a plasma containing sulfur ions, for the sulfidizing. The plasma containing sulfur ions is based on gaseous hydrogen sulfide, in particular.

In accordance with at least one embodiment, the telluridizing is carried out by means of a tellurium-containing atmosphere, solution and/or plasma.

In accordance with at least one embodiment, the selenidizing is carried out by means of a selenium-containing atmosphere, solution and/or plasma.

In accordance with at least one embodiment, step C) is carried out in a structured fashion. In particular, step C) is carried out by means of printing methods, such as, for example, inkjet methods or gravure printing, or vapor deposition.

In accordance with at least one embodiment, the conductive current spreading structure is shaped in step C) by applying at least one metal or an alloy on the first electrode over the whole area and then selectively removing the metal or the alloy. In other words, the metal or the alloy of the conductive current spreading structure is applied over the whole area of the substrate in an unstructured fashion. The conductive current spreading structure is subsequently produced for example by means of etching processes.

### BRIEF DESCRIPTION OF DRAWINGS

Further advantages, advantageous embodiments and developments will become apparent from the embodiments described below in association with the figures.

In the figures:

FIGS. 1A and B show a schematic illustration of an organic light-emitting component in accordance with a comparative example,

FIG. 1C shows a schematic side view of an organic light-emitting component in accordance with one embodiment,

FIG. 2 shows a schematic plan view of an organic light-emitting component in accordance with one embodiment,

FIGS. 3A and 3B each show a schematic side view of an excerpt from an organic light-emitting component in accordance with one embodiment,

FIGS. 4A and 4B each show a schematic side view of an excerpt from an organic light-emitting component in accordance with one embodiment,

FIGS. 5A to 5F show a method for producing an organic light-emitting component in accordance with one embodiment,

FIGS. 6A to 6D show a method for producing an organic light-emitting component in accordance with one embodiment,

FIGS. 7A to 7D show a method for producing an organic light-emitting component in accordance with one embodiment, and

FIGS. 8A to 8E show a method for producing an organic light-emitting component in accordance with one embodiment.

In the embodiments and figures, elements that are identical, act identically or are of identical type may be provided in each case with the same reference signs. The illustrated elements and their size relationships among one another should not be regarded as true to scale. Rather, individual elements such as, for example, layers, structural parts, components and regions may be illustrated with an exaggerated size in order to enable better illustration and/or in order to afford a better understanding.

### DETAILED DESCRIPTION

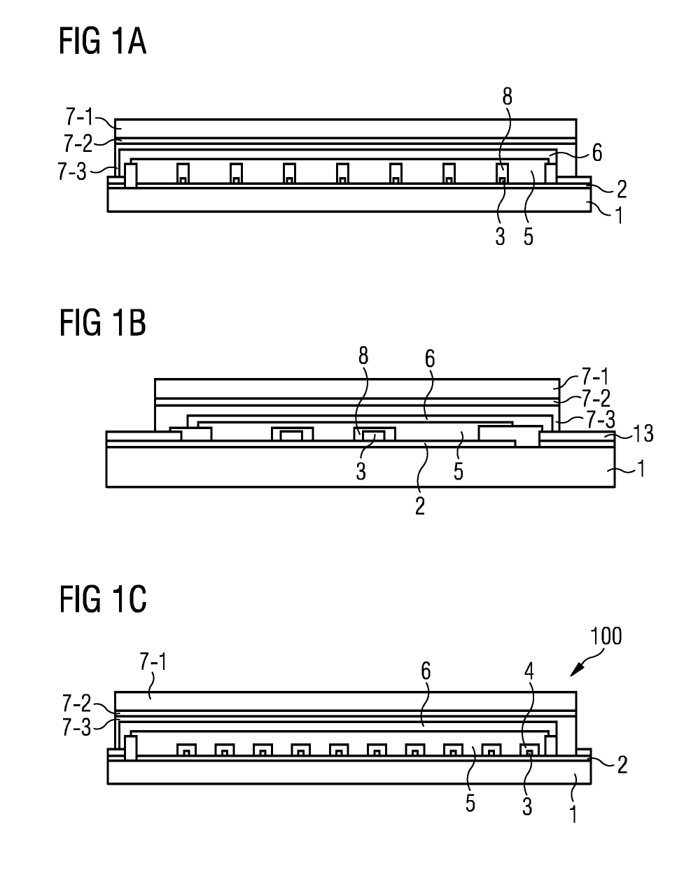

FIGS. 1A and 1B each show a schematic side view of an organic light-emitting component in accordance with a comparative example. The components each include a substrate 1, a first electrode 2, conductive current spreading structures 3, a second electrode 6 and an organic functional layer stack 5. The electrodes 2, 6 can be shaped as transparent or non-transparent. The electrodes 2, 6 can be shaped in particular in each case from ITO, thin metal layers, conductive network structures, graphene or combinations thereof. At least the organic functional layer stack 5 is protected from environmental influences by means of an encapsulation 7. The encapsulation 7 includes a thin film coating (TFE) 7-3, an adhesive layer 7-2 and a glass 7-1. A substrate 1, a protective glass or other protective layers can also be used instead of the glass 7-1. Alternatively, a cavity encapsulation can be used for the thin film coating (TFE) 7-3. The component in FIG. 1B includes a further contact layer 13. The further contact layer 13 can also be absent, such that a direct contacting on the first electrode 2 can also be effected. The conductive current spreading structures 3 are protected by an organic insulator layer 8 against the organic functional layer stack 5 applied subsequently by vapor deposition. The organic insulation layer 8 is polyimide, in particular, and can be applied by means of mask processes, for example. The organic insulation layer 8 has a high resist height of, in particular, 1 μm to 7 μm, that is to say projects very far into the organic functional layer stack 5. As a result, the conductive current spreading structures 3 are visible in a plan view of the component 100. Furthermore, a short circuit and/or instances of permeability can arise as a result of the great difference in height at the conductive current spreading structures 3 during the deposition of the organic functional layer stack 5 and/or the encapsulation 7. The organic insulation layer 8, which includes in particular organic compounds, may evaporate during the fabrication process, such that decomposition products of the organic compound of the organic insulation layer 8 may pass into the organic functional layer stack 5. The lifetime of the organic light-emitting component 100 may thus be reduced.

FIG. 1C shows a schematic side view of an organic light-emitting component 100 in accordance with one embodiment. FIG. 1C differs in comparison with the comparative examples in FIGS. 1A and 1B in that here an inorganic passivation layer 4 is used instead of an organic insulation layer 8. In particular, the first electrode 2 is shaped as an anode and the inorganic passivation layer 4 as an n-type semiconductor, such that transport of holes from the first electrode 2 via the inorganic passivation layer 4 in the direction of the organic functional layer stack 5 is prevented. The inorganic passivation layer 4 thus serves for hole insulation for the conductive current spreading structures 3 of the anode. The inorganic passivation 4 layer has in particular a layer thickness of ≤10 nm. In particular, the inorganic passivation layer 4 molds over both the side faces 3-2 and the surface 3-1 of the respective conductive current spreading structure 3. Surface 3-1 here means the surface facing away from the substrate 1. The inorganic passivation layer 4 is in particular a sulfide, selenide and/or telluride of the at least one metal of the conductive current spreading structure 3. In particular, the formation of sulfide is carried out by means of an atmosphere including hydrogen sulfide, a solution containing sulfur ions or containing sulfur or a plasma containing sulfur ions or containing sulfur.

If the conductive current spreading structure 3 preferably includes silver, then the inorganic passivation layer 4 is formed from silver sulfide, that is to say Ag₂S. The external contacts can be exposed by ablation or temporary covering, for example by a protective layer 11. The protective layer 11 can be a sulfide, for example. As a result of the use of an inorganic passivation layer 4 in an organic light-emitting component 100, the distance and/or the shape and/or the width of the conductive current spreading structures 3 can be configured in a variable manner and a homogeneous luminous area can nevertheless be set. The conductive current spreading structures 3 can be formed such that they are very narrow in their width and are thus virtually invisible. It is thus possible to apply many conductive current spreading structures 3, which contribute to an improved uniform emission of the radiation emitted by the organic functional layer stack 5. The covering of the conductive current spreading structures 3 with an inorganic passivation layer 4, which is shaped in particular in a very thin fashion, enables the organic functional layer stack 5 to be applied in an improved manner. At the same time, the first electrode 2, which is shaped from TCO, for example, can be treated and thus the sheet resistance can be reduced and the work function can be altered. Moreover, the inorganic passivation layer 4 prevents a direct current flow from the first electrode 2 in the direction of the organic functional layer stack 5, for example into the hole transport layer and/or hole injection layer, which are preferably arranged between the first electrode 2 and the organic functional layer stack 5.

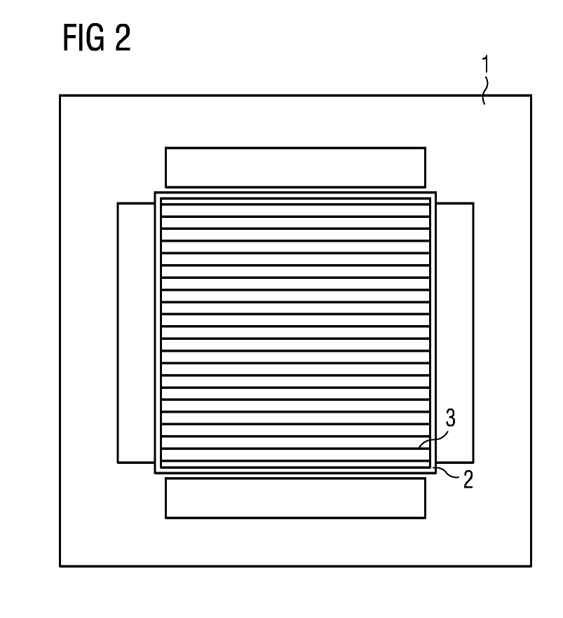

FIG. 2 shows a schematic plan view of an excerpt from an organic light-emitting component 100 in accordance with one embodiment. FIG. 2 shows the lead structures of the conductive current spreading structure 3 on a first electrode 2, said lead structures running parallel to one another. The lead structures running parallel to one another of the conductive current spreading structure 3 can be covered with an inorganic passivation layer 4 (not shown here).

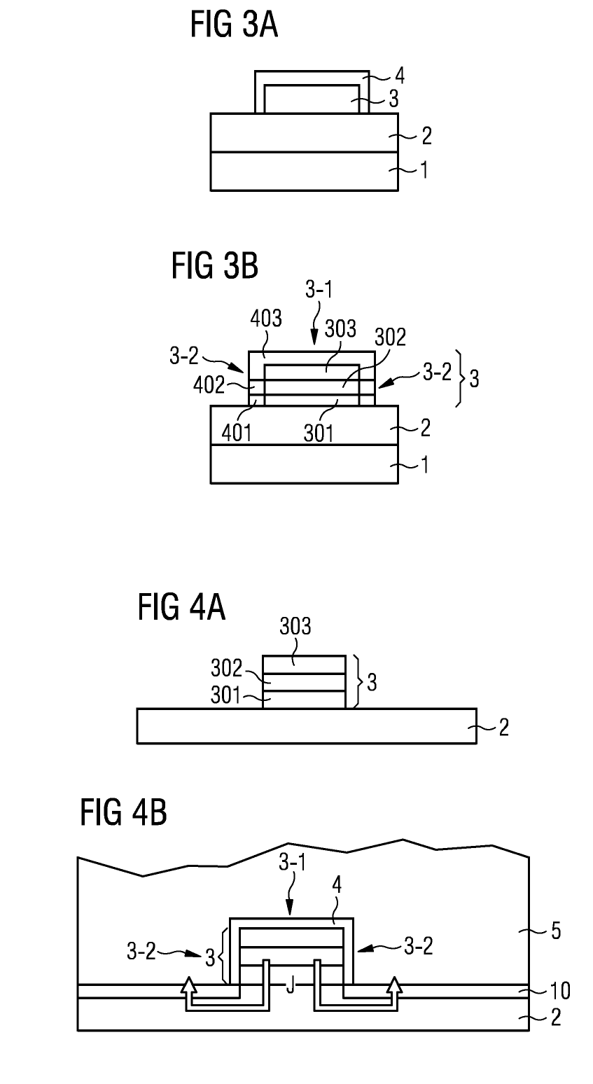

FIGS. 3 to 8 each show only one conductive current spreading structure 3. However, the description given here is analogously also applicable to more than one conductive current spreading structure 3. FIGS. 2 to 8 can furthermore have one or a plurality of hole transport layers and/or hole injection layers, in particular between the organic functional layer stack 5 and the anode, and/or one or a plurality of electron transport layers and/or electron injection layers, in particular between the organic functional layer stack 5 and the cathode (not shown here).

FIGS. 3A and 3B each show a schematic excerpt from an organic light-emitting component 100 in accordance with one embodiment. FIG. 3A shows a substrate 1 and, disposed downstream, a first electrode 2, a conductive current spreading structure 3 and an inorganic passivation layer 4. The substrate 1 can be composed of glass, for example. The first electrode 2 is shaped in particular as an anode and is transparent or semitransparent. A conductive current spreading structure 3 including a metal or consisting of a metal is arranged in direct mechanical contact on the first electrode 2. The conductive current spreading structure 3 is covered by an inorganic passivation layer 4 here on all sides, that is to say from all sides, in particular from three sides. In this case, the inorganic passivation layer 4 consists of or includes preferably the sulfide of the metal of the conductive current spreading structure 3. If the conductive current spreading structure 3 is shaped from silver, for example, then the inorganic passivation layer 4 includes silver sulfide as material.

FIG. 3B differs from FIG. 3A in that the conductive current spreading structure 3 has a layer construction 301, 302, 303. The layers of the conductive current spreading structure include different metals, in particular. In particular, adjacent layers include different metals. By way of example, the lower layer 301 can consist of silver, the layer 302 of a further arbitrary metal and the layer 303 of silver. The inorganic passivation layer 4 thus likewise has a different composition, in particular a layer construction 401, 402, 403. The inorganic passivation layer 4 includes silver sulfide where the layer 303 is arranged, a sulfide of the metal where the layer 302 is arranged, and silver sulfide where the layer 301 is arranged. It is thus possible to produce an inorganic passivation layer 4 including a mixture of different sulfides 401, 402, 403 of the metals of the conductive current spreading structure 3.

FIGS. 4A and 4B each show a schematic side view of an excerpt from an organic light-emitting component 100 in accordance with one embodiment. FIG. 4A shows a first electrode 2, over which a conductive current spreading structure 3 is arranged. The conductive current spreading structure 3 includes a layer sequence 301, 302, 303. FIG. 4B shows the implemented sulfidizing of the conductive current spreading structure and thus the formation of the inorganic passivation layer 4 at least on the surface 3-1 and at the side faces 3-2 of the conductive current spreading structure 3. The formation of an inorganic passivation layer 4 makes it possible to prevent a direct current flow from the conductive current spreading structure 3 into the organic functional layer stack 5, such that the current flow J passes via the first electrode 2 into the organic functional layer stack 5. In particular, this is the case if the first electrode 2 is shaped as an anode and the inorganic passivation layer 4 is an n-type semiconductor or the first electrode is shaped as a cathode and the inorganic passivation layer 4 is a p-type semiconductor. The inorganic passivation layer 4 thus insulates the conductive current spreading structure 3 and at least one organic functional layer stack 5, that is to say prevents hole transport of the holes injected by the anode or electron transport of the electrons injected by the cathode. The component 100 may include a further layer 10, which is a hole injection layer and/or hole transport layer, for example. Instead of a layer construction of the conductive current spreading structure 3, the latter can also be a monolayer composed of a metal, preferably silver.

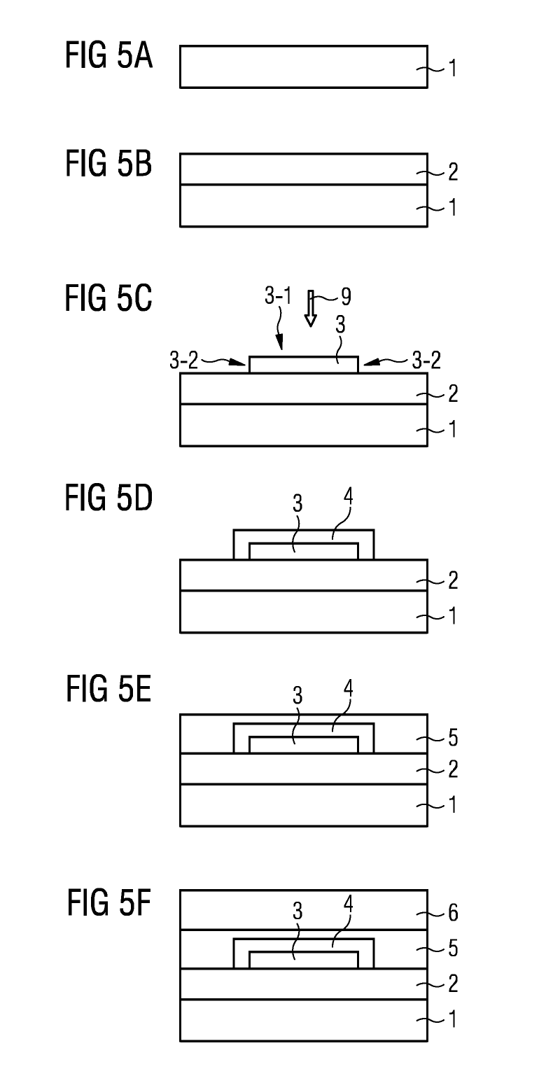

FIG. 5 shows a method for producing an organic light-emitting component 100 in accordance with one embodiment. FIG. 5A shows the provision of a substrate 1. In FIG. 5B, a first electrode 2 is applied on the substrate 1. In particular, the first electrode 2 is applied directly on the substrate 1. FIG. 5C shows the application of at least one conductive current spreading structure 3 on the first electrode 2. The conductive current spreading structure 3 has a surface 3-1 facing away from the substrate, and side faces 3-2. The conductive current spreading structure 3 can be produced by applying the material of the conductive current spreading structure 3 over the whole area on the substrate 1 or the first electrode 2. Alternatively or additionally, the conductive current spreading structure 3 can also be applied only selectively on the first electrode 2. Afterward, the component can be treated in FIG. 5C (illustrated by an arrow 9). The treatment 9 can be carried out with an atmosphere including hydrogen sulfide, a solution containing sulfur or containing sulfur ions, or a plasma containing sulfur or containing sulfur ions. An inorganic passivation layer 4 is formed as a result, as shown in FIG. 5D. The inorganic passivation layer 4 includes in particular sulfides of the metal or of the alloy of the conductive current spreading structure 3. Thus, no additional material is applied on the conductive current spreading structure 3, rather the inorganic passivation layer 4 is produced in situ from the conductive current spreading structure 3. In FIG. 5E, subsequently an organic functional layer stack 5 is applied at least on the inorganic passivation layer 4 and at least partly on the first electrode 2. In FIG. 5F, the application of a second electrode 6 is subsequently carried out.

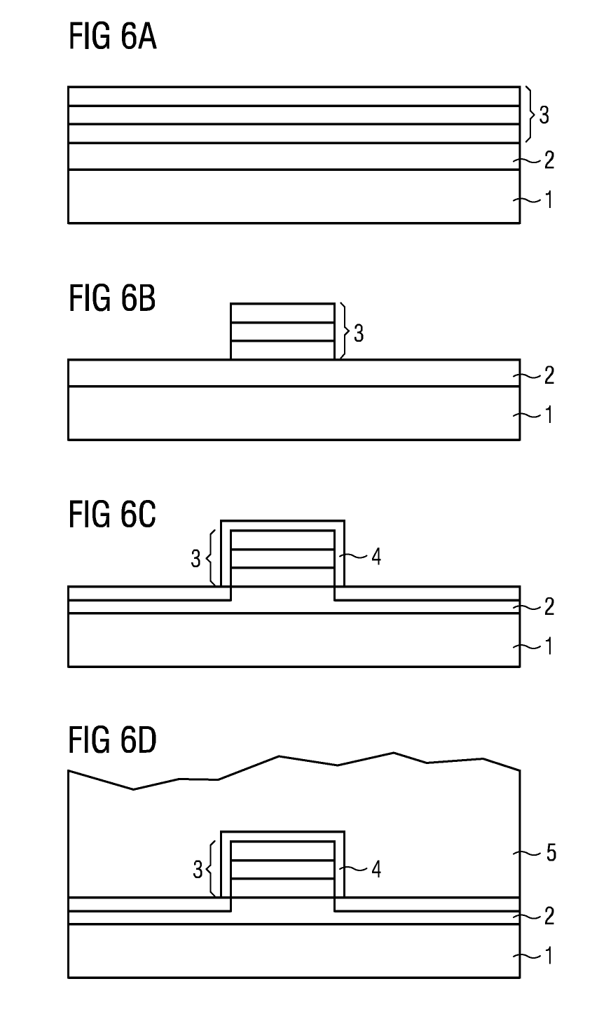

FIG. 6 shows a schematic method for producing an organic light-emitting component 100 in accordance with one embodiment. FIG. 6A shows the provision of a substrate 1 and a first electrode 2. A material for a conductive current spreading structure 3 is applied on said first electrode 2 over the whole area and in an unstructured fashion. The conductive current spreading structure 3 is subsequently produced, for example by means of etching processes. At least one conductive current spreading structure 3 results (FIG. 6B). In FIG. 6C, the treatment of at least the conductive current spreading structure 3 is subsequently carried out by means of an atmosphere including hydrogen sulfide, a solution containing sulfur ions, and/or a plasma containing sulfur ions, such that an inorganic passivation layer 4 is produced. The inorganic passivation layer 4 forms selectively on the conductive current spreading structures 3 and has an insulating effect at least for holes or electrons. The inorganic passivation layer 4 is formed in particular from the sulfide of the metal of the conductive current spreading structure 3. FIG. 6D shows the application of the organic functional layer stack 5. Instead of a layer construction of the conductive current spreading structure 3, the latter can also be a monolayer composed of a metal, preferably silver.

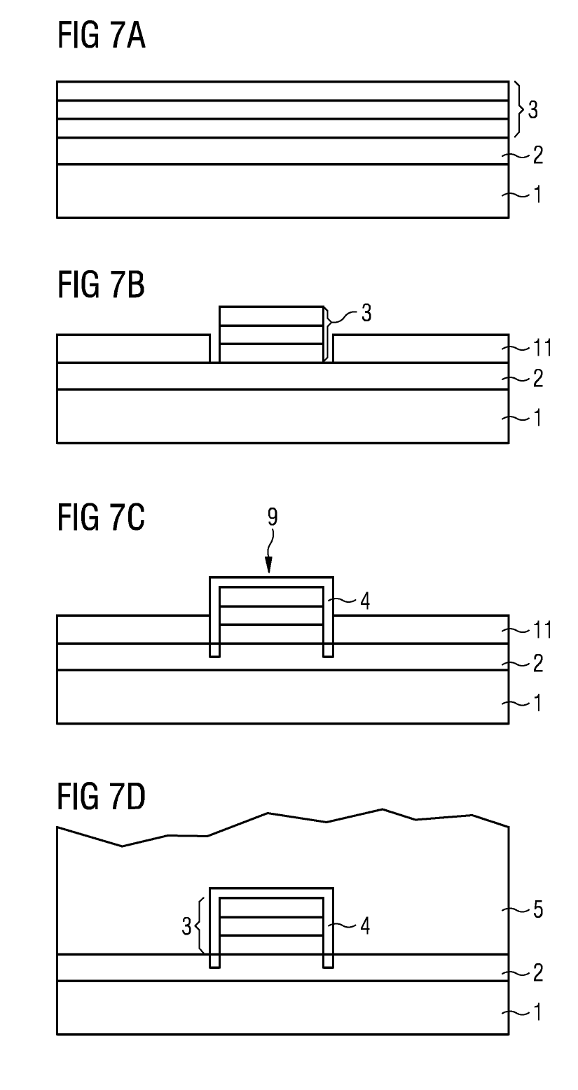

FIG. 7 shows a schematic method for producing an organic light-emitting component 100 in accordance with one embodiment. FIG. 7A shows a substrate 1, a second electrode 2 and a material for the conductive current spreading structure 3, said material being applied over the whole area on the second electrode 2. The material is subsequently structured in order to form a conductive current spreading structure 3 (not shown here). A protective layer 11, which is in particular an oxide, selenide, telluride or sulfide protective layer, is subsequently applied selectively, that is to say on the free areas of the first electrode 2 which are not covered by the conductive current spreading structure 3. The first electrode 2 is thus protected against sulfidizing. In FIG. 7C, the treatment 9 is subsequently carried out for example by means of hydrogen sulfide, the conductive current spreading structure 3 then forming an inorganic passivation layer 4. On account of the protective layer 11, the first electrode 2, for example composed of TCO, is protected against this sulfidizing. Afterward, the protective layer 11 can be removed (not shown here) and the organic functional layer stack 5 can be applied (FIG. 7D). Instead of a layer construction of the conductive current spreading structure 3, the latter can also be a monolayer composed of a metal, preferably silver.

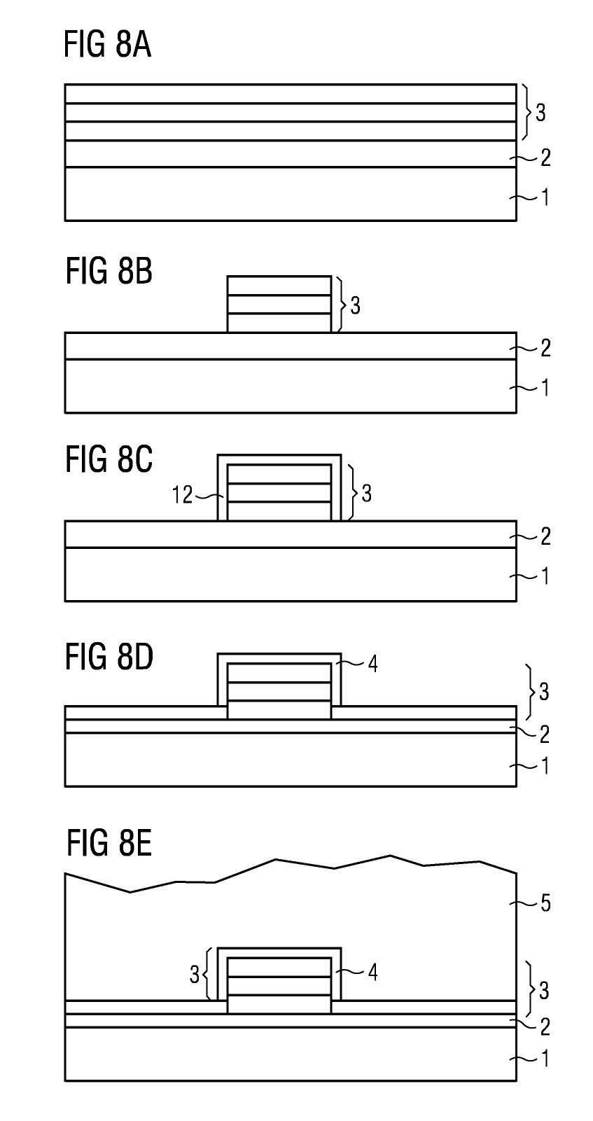

FIG. 8 schematically shows a method for producing an organic light-emitting component 100 in accordance with one embodiment. FIGS. 8A and 8B correspond to FIGS. 6A and 6b. In FIG. 8C, a metal layer 12 is then applied at least on the surface 3-1 and on the side faces 3-2 of the conductive current spreading structure 3. In FIG. 8D, said metal layer 12 is sulfidized or telluridized, for example, such that an inorganic passivation layer 4 forms from the metal layer 12 as a result of treatment, for example with hydrogen sulfide or hydrogen telluride. Alternatively, it is possible for the metal layer also not to be completely sulfidized or telluridized, but rather only in part, such that the metal layer 12 is still present and directly adjoins the inorganic passivation layer 4. FIG. 8E corresponds to FIG. 6D. Instead of a layer construction of the conductive current spreading structure 3, the latter can also be a monolayer composed of a metal, preferably silver.

The components 100 illustrated in FIGS. 3 to 8 can additionally include an encapsulation 7.

By virtue of the disclosure, the electrically conductive current spreading structure 3 is simultaneously insulated vis-à-vis holes or electrons, such that no current flows directly via the passivation layer 4 and this improves the properties of the first electrode 2, which is composed of ITO, for example, with respect to the low resistance. Moreover, a thinner structure to be covered is created for the encapsulation 7.

It is advantageous that the inorganic passivation layer 4 is compatible with processes that have an influence on electro-optical parameters, storage time and/or long-term stability.

In the proposed process, the etched and exposed metal structures (contacts, busbars) are treated, such that an inorganic passivation layer 4 forms which is thick enough that no tunneling current can flow. Thus, additional resist is no longer necessary. The contacts in the external region can also be sulfidized or telluridized, but can then be exposed again by means of etching or ablation processes, for example. In principle, all of the contacts can thus be treated.

The embodiments described in association with the figures and the features thereof can also be combined with one another in accordance with further embodiments, even if such combinations are not shown explicitly in the figures. Furthermore, the embodiments explained in association with the figures can have additional or alternative features in accordance with the description in the general part.

The disclosure is not restricted to the embodiments by the description on the basis of said embodiments. Rather, the disclosure encompasses any novel feature and also any combination of features, which in particular includes any combination of features in the patent claims, even if this feature or this combination itself is not explicitly specified in the patent claims or embodiments.

1. An organic light-emitting component comprising,
a substrate;
a first electrode arranged over the substrate;
at least one organic functional layer stack which is configured to emit radiation, and is arranged at least over the first electrode;
at least one conductive current spreading structure which is arranged on the first electrode, and faces the at least one organic functional layer stack; and
a second electrode arranged over the at least one organic functional layer stack,
wherein the at least one conductive current spreading structure comprises at least one metal,
wherein the at least one conductive current spreading structure is covered with an inorganic passivation layer,
wherein the inorganic passivation layer comprises a sulfide, a selenide and/or a telluride of the at least one metal of the at least one conductive current spreading structure, and
wherein the inorganic passivation layer is either an n-type semiconductor or a p-type semiconductor, such that no current flows between the at least one conductive current spreading structure and the at least one organic functional layer stack via the inorganic passivation layer.

2. The organic light-emitting component as claimed in claim 1,
wherein the inorganic passivation layer is produced by sulfidizing the at least one metal of the at least one conductive current spreading structure.

3. The organic light-emitting component as claimed in claim 1,
wherein the first electrode is an anode, and
the inorganic passivation layer is the n-type semiconductor, such that hole transport from the first electrode via the inorganic passivation layer in a direction of the at least one organic functional layer stack is prevented.

4. The organic light-emitting component as claimed in claim 1,
wherein the at least one metal of the at least one conductive current spreading structure comprises silver, and
the inorganic passivation layer comprises silver sulfide.

5. The organic light-emitting component as claimed in claim 1,
wherein the organic light-emitting component is configured to emit the radiation generated by the at least one organic functional layer stack via the first electrode and the substrate.

6. The organic light-emitting component as claimed in claim 1,
wherein the at least one metal of the at least one conductive current spreading structure comprises silver and
the inorganic passivation layer is produced by telluridizing at least the silver of the at least one conductive current spreading structure.

7. The organic light-emitting component as claimed in claim 1,
wherein the first electrode or the second electrode is a cathode, and
the inorganic passivation layer is the p-type semiconductor, such that electron transport from the first electrode or the second electrode via the inorganic passivation layer in a direction of the at least one organic functional layer stack is prevented.

8. The organic light-emitting component as claimed in claim 7,
wherein the second electrode is a cathode, and
the organic light-emitting component is configured to emit the radiation generated by the at least one organic functional layer stack via the first electrode and the second electrode.

9. The organic light-emitting component as claimed in claim 1,
wherein the inorganic passivation layer is a mixture of at least two different metal sulfides.

10. The organic light-emitting component as claimed in claim 1,
wherein the inorganic passivation layer has a layer thickness of between 10 nanometers (nm) and 100 nm inclusive.

11. The organic light-emitting component as claimed in claim 1,
wherein the at least one conductive current spreading structure has a surface facing away from the substrate, and side faces,
wherein the inorganic passivation layer directly covers the surface and the side faces.

12. The organic light-emitting component as claimed in claim 1,
wherein the at least one conductive current spreading structure comprises a metal layer, which directly covers a surface facing away from the substrate and side faces of the at least one conductive current spreading structure,
wherein the inorganic passivation layer is produced by sulfidizing the at least one metal layer and covers at least the surface and the side faces of the at least one conductive current spreading structure.

13. The organic light-emitting component as claimed in claim 12,
wherein the metal layer comprises silver and
the inorganic passivation layer comprises silver sulfide.

14. A method for producing an organic light-emitting component, the method comprising the following steps:
providing a substrate;
applying a first electrode on the substrate;
applying at least one conductive current spreading structure on the first electrode, the at least one conductive current spreading structure comprising at least one metal, and having a surface facing away from the substrate, and side faces;
selectively forming an inorganic passivation layer at least on the surface and the side faces of the at least one conductive current spreading structure, the inorganic passivation layer comprising a sulfide, a telluride and/or a selenide of the at least one metal of the at least one conductive current spreading structure, the at least one conductive current spreading structure being covered with the inorganic passivation layer;
applying an organic functional layer stack at least on the inorganic passivation layer and at least partly on the first electrode; and
applying a second electrode,
wherein the inorganic passivation layer is either an n-type semiconductor or a p-type semiconductor, such that no current flows between the at least one conductive current spreading structure and the organic functional layer stack via the inorganic passivation layer.

15. The method as claimed in claim 14, further comprising:
prior to said selectively forming an inorganic passivation layer, selectively applying a protective layer on regions of the first electrode which are free of the at least one conductive current spreading structure; and
removing the protective layer after said selectively forming an inorganic passivation layer.

16. The method as claimed in claim 14,
wherein said selectively forming an inorganic passivation layer comprises:
selectively forming the inorganic passivation layer by means of an atmosphere comprising hydrogen sulfide, a sulfur-containing solution or a sulfur-containing plasma.
